(19) United States
(12) Patent Application Publication
(10) Pub. No.: US 2025/0343166 A1
(43) Pub. Date: Nov. 6, 2025

(54) CHIP PACKAGE STRUCTURE WITH RING STRUCTURE AND METHOD FOR FORMING THE SAME

(71) Applicant: Taiwan Semiconductor Manufacturing Co., Ltd., Hsinchu (TW)

(72) Inventors: Chun-Yen Lan, Hsinchu (TW); Yu-Hsun Wang, Zhubei City (TW); Pu Wang, Hsinchu (TW); Li-Hui Cheng, New Taipei City (TW); Ying-Ching Shih, Hsinchu (TW)

(21) Appl. No.: 19/268,329

(22) Filed: Jul. 14, 2025

Related U.S. Application Data
(63) Continuation of application No. 18/672,882, filed on May 23, 2024.
(60) Provisional application No. 63/613,219, filed on Dec. 21, 2023.

(51) Int. Cl. H01L 23/00; H01L 21/56; H01L 23/367; H01L 23/498; H01L 25/16

(52) U.S. Cl. CPC H01L 23/562; H01L 21/56; H01L 23/49838; H01L 23/3672; H01L 24/16; H01L 24/32; H01L 24/73; H01L 25/16; H01L 2224/16225; H01L 2224/32225; H01L 2224/73204; H01L 2924/1436

(57) ABSTRACT

A chip package structure is provided. The chip package structure includes a wiring substrate. The chip package structure includes a chip structure over the wiring substrate. The chip package structure includes a first ring structure over the wiring substrate and surrounding the chip structure, wherein a first coefficient of thermal expansion of the first ring structure is less than a second coefficient of thermal expansion of the wiring substrate. The chip package structure includes an anti-warpage structure over the first ring structure. A third coefficient of thermal expansion of the anti-warpage structure is greater than the first coefficient of thermal expansion of the first ring structure.

### PRIORITY CLAIM AND CROSS-REFERENCE

This application is a continuation of U.S. patent application Ser. No. 18/672,882, filed on May 23, 2024, which claims the benefit of U.S. Provisional Application No. 63/613,219, filed on Dec. 21, 2023, and entitled “Equivalent ring and lid for Package Warpage Control and Stress Mitigation”, the entirety of which are incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating layers or dielectric layers, conductive layers, and semiconductor layers over a semiconductor substrate, and patterning the various material layers using photolithography processes and etching processes to form circuit components and elements thereon.

Many integrated circuits are typically manufactured on a semiconductor wafer. The dies of the wafer may be processed and packaged. Since the chip package structure may need to include chips and a wiring substrate with different coefficients of thermal expansion (CTE), it is a challenge to form a reliable chip package structure.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a chip package structure, in accordance with some embodiments.

FIG. 1E-1 is a top view of the chip package structure of FIG. 1E, in accordance with some embodiments.

FIG. 2A is a cross-sectional view of a chip package structure, in accordance with some embodiments.

FIG. 2B is a top view of the chip package structure of FIG. 2A, in accordance with some embodiments.

FIG. 3A is a cross-sectional view of a chip package structure, in accordance with some embodiments.

FIG. 3B is a top view of the chip package structure of FIG. 3A, in accordance with some embodiments.

FIG. 4A is a cross-sectional view of a chip package structure, in accordance with some embodiments.

FIG. 4B is a top view of the chip package structure of FIG. 4A, in accordance with some embodiments.

FIG. 5A is a cross-sectional view of a chip package structure, in accordance with some embodiments.

FIG. 5B is a top view of the chip package structure of FIG. 5A, in accordance with some embodiments.

FIG. 6A is a cross-sectional view of a chip package structure, in accordance with some embodiments.

FIG. 6B is a top view of the chip package structure of FIG. 6A, in accordance with some embodiments.

FIG. 7 is a flow chart illustrating a process for forming a chip package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

The present disclosure pertains to a chip package structure and a method for forming the same, which are beneficial for controlling package warpage and mitigating stress within semiconductor packages. As electronic devices continue to evolve, there is an increasing demand for semiconductor packages that can maintain structural integrity and reliability even as package sizes grow and substrate thicknesses decrease. The disclosed technology addresses these challenges by introducing a hybrid ring and lid structure that manages package stress, warpage, and coplanarity more effectively than traditional packaging solutions.

In some embodiments, the chip package structure incorporates a first ring structure characterized by high rigidity and a low coefficient of thermal expansion (CTE). This first ring structure is combined with a substrate to form a low CTE equivalent body, which serves as the foundation for the chip package. The disclosure includes the addition of a second ring structure or an anti-warpage lid, which possesses a higher CTE than the first ring structure. The contrast in CTE between these components introduces a controlled stepwise warpage management approach, which helps to reduce the overall stress experienced by the package during thermal cycling and other reliability tests.

The disclosed chip package structure is can be applied to Chip on Wafer on Substrate (CoWoS) and Integrated Fan-Out (InFO) packaging technologies, where it can be used in both core and coreless substrate-based topologies. By implementing a hybrid structure with specific CTE combinations, the disclosed technology controls warpage and also enhances the coplanarity of the package, improving yield and performance of the semiconductor devices.

The detailed description that follows further illustrates various embodiments of the chip package structure. The benefits of the disclosed technology include improved structural integrity, reduced package stress, and enhanced reliability of the semiconductor packages.

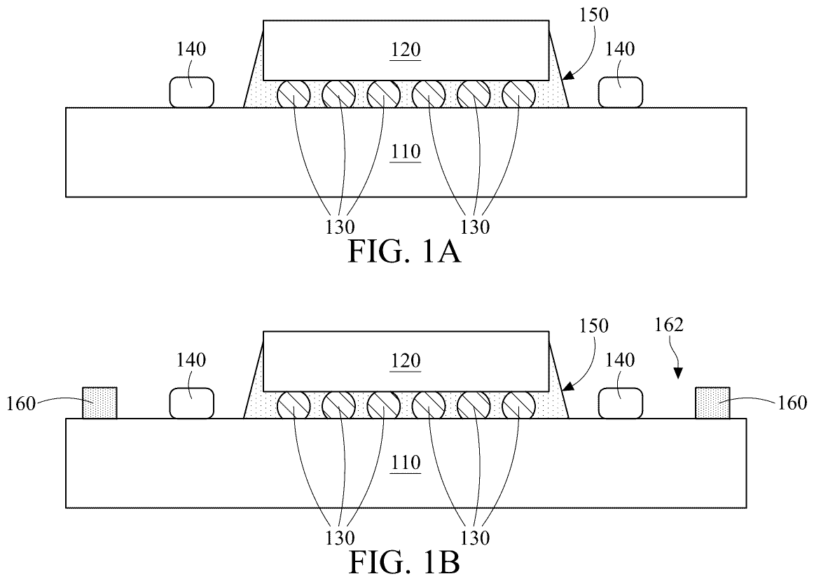

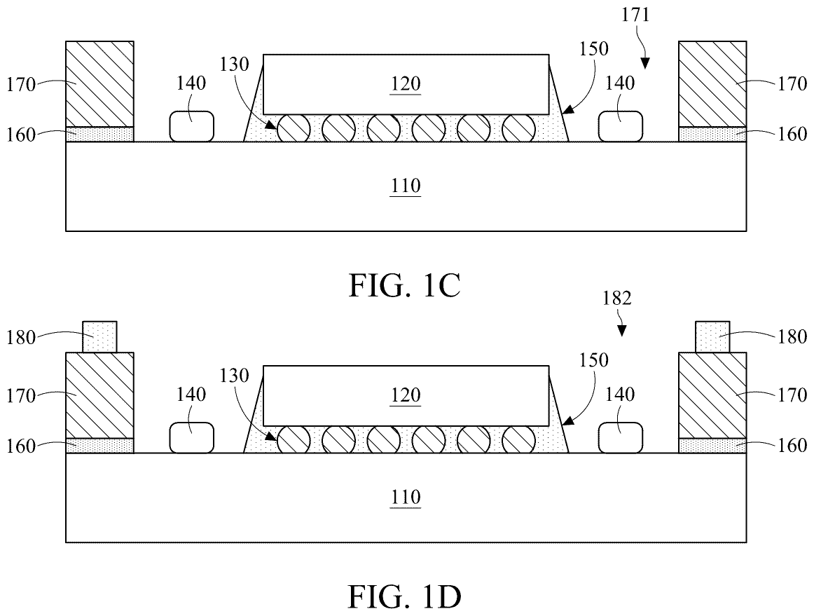

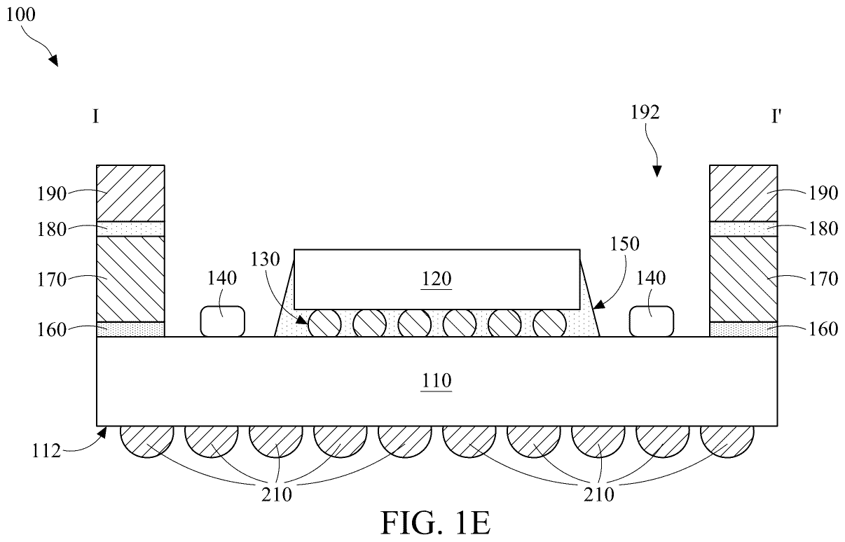

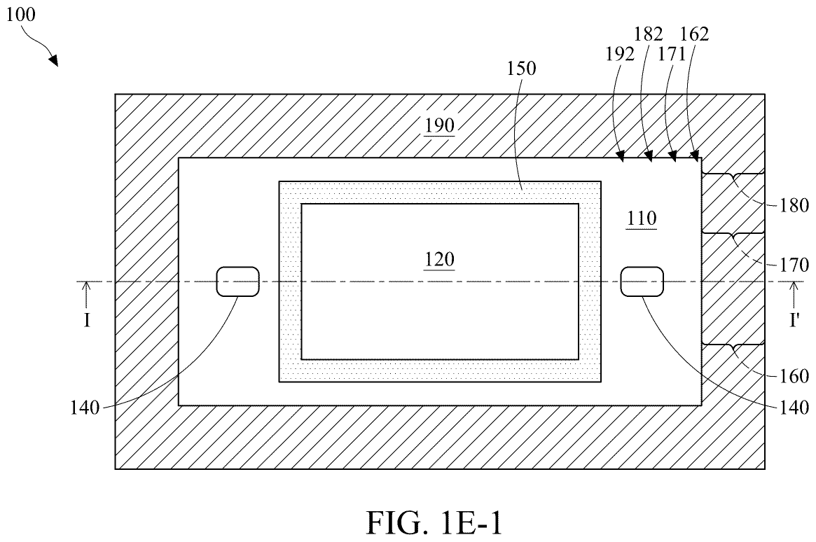

FIGS. 1A-1E are cross-sectional views of various stages of a process for forming a chip package structure, in accordance with some embodiments. As shown in FIG. 1A, a wiring substrate 110 is provided, in accordance with some embodiments.

The wiring substrate 110 includes a dielectric layer, conductive pads, wiring layers, and conductive vias (not shown), in accordance with some embodiments. The conductive pads are embedded in the dielectric layer, in accordance with some embodiments.

The wiring layers and the conductive vias of the wiring substrate 110 are formed in the dielectric layer of the wiring substrate 110, in accordance with some embodiments. The conductive vias are electrically connected between different wiring layers and between the wiring layer and the conductive pads, in accordance with some embodiments.

The dielectric layer is made of an insulating material such as a polymer material (e.g., polybenzoxazole or polyimide), nitride (e.g., silicon nitride), oxide (e.g., silicon oxide), silicon oxynitride, or the like, in accordance with some embodiments. The dielectric layer is formed using lamination process (or deposition processes), photolithography processes, and etching processes, in accordance with some embodiments.

The conductive pads are made of a conductive material, such as metal (e.g. copper, aluminum, or tungsten) or alloys thereof, in accordance with some embodiments. The wiring layers are made of a conductive material, such as metal (e.g. copper, aluminum, or tungsten) or alloys thereof, in accordance with some embodiments. The conductive vias are made of a conductive material, such as metal (e.g. copper, aluminum, or tungsten) or alloys thereof, in accordance with some embodiments.

In some embodiments, the conductive pads, the wiring layers, and the conductive vias are made of the same material. In some embodiments, the conductive pads, the wiring layers, and the conductive vias are made of different materials.

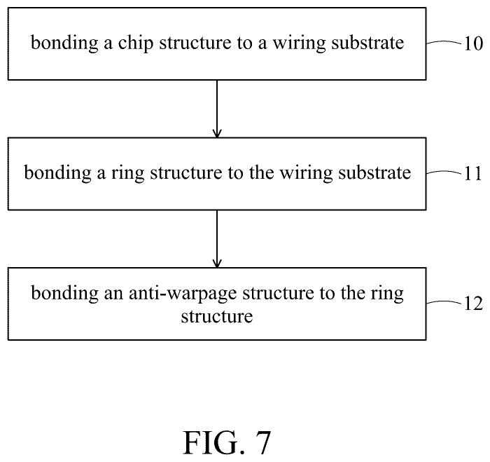

FIG. 7 is a flow chart illustrating a process for forming a chip package structure, in accordance with some embodiments. As shown in FIGS. 1A and 7, the step 10 is performed to bond a chip structure 120 to the wiring substrate 110 through conductive bumps 130, in accordance with some embodiments. In some embodiments, the chip structure 120 includes a chip. The chip structure 120 includes a substrate, in accordance with some embodiments. In some embodiments, the substrate is made of an elementary semiconductor material including silicon or germanium in a single crystal structure, a polycrystalline structure, or an amorphous structure.

In some other embodiments, the substrate is made of a compound semiconductor, such as silicon carbide, gallium arsenide, gallium phosphide, indium phosphide, or indium arsenide; an alloy semiconductor, such as SiGe, or GaAsP; or a combination thereof. The substrate may also include multi-layer semiconductors, semiconductor on insulator (SOI) (such as silicon on insulator or germanium on insulator), or a combination thereof.

In some embodiments, the substrate includes various device elements. In some embodiments, the various device elements are formed in and/or over the substrate. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

In some other embodiments, the chip structure 120 includes a chip package, such as dynamic random access memory (DRAM) packages. The chip package includes a chip scale package, such as a wafer level chip scale package. In some embodiments, the chip package includes one chip. In some other embodiments, the chip package includes multiple chips, which are arranged side by side or stacked with each other (e.g., a 3D packaging or a 3DIC device).

In some embodiments, the chip structure 120 is a chip, such as a central processing unit (CPU) chip. The conductive bumps 130 are made of tin (Sn) or another suitable conductive material, in accordance with some embodiments.

As shown in FIG. 1A, devices 140 are bonded to the wiring substrate 110 by, for example, surface mount technology (SMT), in accordance with some embodiments. The devices 140 include passive devices, other suitable devices, or combinations thereof. The passive devices include resistors, capacitors, inductors, or other suitable passive devices.

As shown in FIG. 1A, an underfill layer 150 is formed between the chip structure 120 and the wiring substrate 110, in accordance with some embodiments. The underfill layer 150 surrounds the conductive bumps 130 and the chip structure 120, in accordance with some embodiments. The underfill layer 150 is made of an insulating material, such as a polymer material, in accordance with some embodiments.

As shown in FIG. 1B, an adhesive layer 160 is formed over the wiring substrate 110, in accordance with some embodiments. The adhesive layer 160 has an opening 162, in accordance with some embodiments. The chip structure 120 is in the opening 162, in accordance with some embodiments.

The adhesive layer 160 is made of a polymer material such as epoxy or silicone, in accordance with some embodiments. The adhesive layer 160 is formed using a dispensing process, in accordance with some embodiments.

As shown in FIGS. 1C and 7, the step 11 is performed to bond a ring structure 170 to the wiring substrate 110 through the adhesive layer 160, in accordance with some embodiments. The adhesive layer 160 is between the ring structure 170 and the wiring substrate 110, in accordance with some embodiments. The ring structure 170 surrounds the chip structure 120, in accordance with some embodiments. The ring structure 170 has an opening 171, in accordance with some embodiments. The chip structure 120 is in the opening 171, in accordance with some embodiments.

The coefficient of thermal expansion of the ring structure 170 is less than the coefficient of thermal expansion of the wiring substrate 110, in accordance with some embodiments. The rigidity of the ring structure 170 is greater than the rigidity of the wiring substrate 110, in accordance with some embodiments.

As a result, the ring structure 170 and the wiring substrate 110 together form an equivalent body with a lower coefficient of thermal expansion and greater rigidity than the wiring substrate 110, in accordance with some embodiments.

The ring structure 170 is made of a rigid and low-CTE material, such as ceramics or alloys (e.g., Ni-Fe alloys or Ni-Fe-Co alloys), or another suitable material which has a lower CTE and a higher rigidity than the wiring substrate 110, in accordance with some embodiments. In some other embodiments, the ring structure 170 is made of metal (e.g., copper or iron), alloys thereof (e.g., stainless steel), or another suitable material which is more rigid than the wiring substrate 110, in accordance with some embodiments. The bonding process includes a heat clamping process and a curing process, in accordance with some embodiments.

As shown in FIG. 1D, an adhesive layer 180 is formed over the ring structure 170, in accordance with some embodiments. The adhesive layer 180 has an opening 182, in accordance with some embodiments. The chip structure 120 is under (or in) the opening 182, in accordance with some embodiments.

The adhesive layer 180 is made of a combination of polymer and metal (e.g., a silver paste) or a polymer (e.g., epoxy or silicone), in accordance with some embodiments. The adhesive layer 180 is formed using a dispensing process, in accordance with some embodiments.

FIG. 1E-1 is a top view of the chip package structure of FIG. 1E, in accordance with some embodiments. FIG. 1E is a cross-sectional view illustrating the chip package structure along a sectional line I-I′ in FIG. 1E-1, in accordance with some embodiments. As shown in FIGS. 1E, 1E-1, and 7, the step 12 is performed to bond an anti-warpage structure 190 to the ring structure 170 through the adhesive layer 180, in accordance with some embodiments.

The coefficient of thermal expansion of the anti-warpage structure 190 is greater than the coefficient of thermal expansion of the ring structure 170, in accordance with some embodiments. The coefficient of thermal expansion (CTE) of the anti-warpage structure 190 is greater than the coefficient of thermal expansion of the wiring substrate 110, in accordance with some embodiments.

The anti-warpage structure 190 includes a ring structure surrounding the chip structure 120, in accordance with some embodiments. The anti-warpage structure 190 has an opening 192, in accordance with some embodiments. The chip structure 120 is under (or in) the opening 192, in accordance with some embodiments.

The adhesive layer 180 is between the anti-warpage structure 190 and the ring structure 170, in accordance with some embodiments. The adhesive layer 180 is thinner than the anti-warpage structure 190 and the ring structure 170, in accordance with some embodiments. The adhesive layer 180 is softer than the anti-warpage structure 190 and the ring structure 170, in accordance with some embodiments. Therefore, the adhesive layer 180 can buffer the stress between the anti-warpage structure 190 and the ring structure 170, in accordance with some embodiments.

The anti-warpage structure 190 is made of a high CTE and high thermal conductivity material, such as a metal material (aluminum or copper), an alloy material (e.g., stainless steel), aluminum-silicon carbide (AlSiC), or another suitable material with a higher CTE than the ring structure 170 and the wiring substrate 110, in accordance with some embodiments. The bonding process includes a heat clamping process and a curing process, in accordance with some embodiments.

As shown in FIG. 1E, conductive bumps 210 are formed over a surface 112 of the wiring substrate 110, in accordance with some embodiments. The conductive bumps 210 are formed over the conductive pads of the wiring substrate 110, in accordance with some embodiments.

The conductive bumps 210 are electrically connected to the chip structure 120 through the wiring substrate 110 and the conductive bumps 130, in accordance with some embodiments. The conductive bumps 210 are made of tin (Sn) or another suitable conductive material, in accordance with some embodiments. In this step, a chip package structure 100 is substantially formed, in accordance with some embodiments.

The coefficient of thermal expansion of the anti-warpage structure 190 is greater than the coefficient of thermal expansion of the equivalent body, which includes the ring structure 170 and the wiring substrate 110, in accordance with some embodiments.

Since the equivalent body has a lower coefficient of thermal expansion than the wiring substrate 110, the coefficient of thermal expansion (CTE) mismatch between the equivalent body and the (high-CTE) anti-warpage structure 190 is greater than the CTE mismatch between the wiring substrate 110 and the anti-warpage structure 190, in accordance with some embodiments.

Since CTE mismatch can reduce the warpage of the chip package structure, the formation of the equivalent body with a lower CTE can increase the CTE mismatch, thereby reducing the warpage of the chip package structure 100, in accordance with some embodiments. In addition, the high rigidity equivalent body also can reduce the warpage of the chip package structure 100, in accordance with some embodiments. Therefore, the yield of the chip package structure 100 is improved, in accordance with some embodiments.

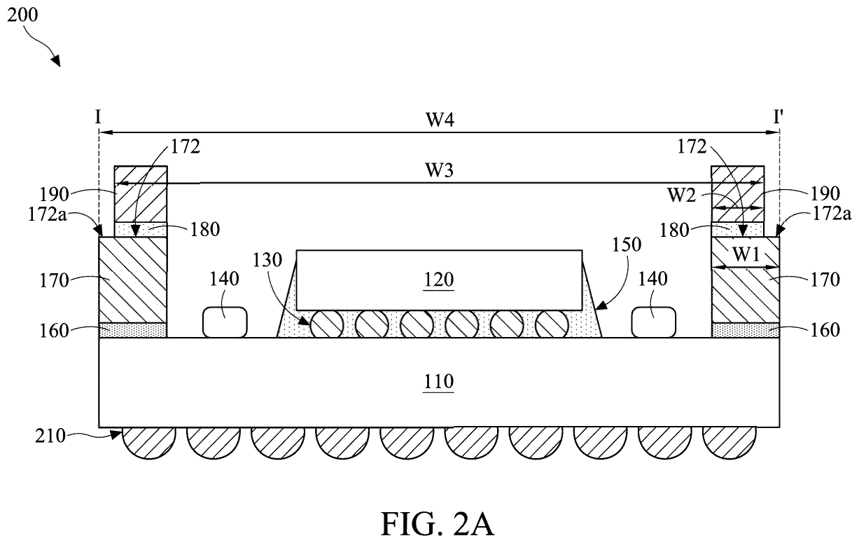

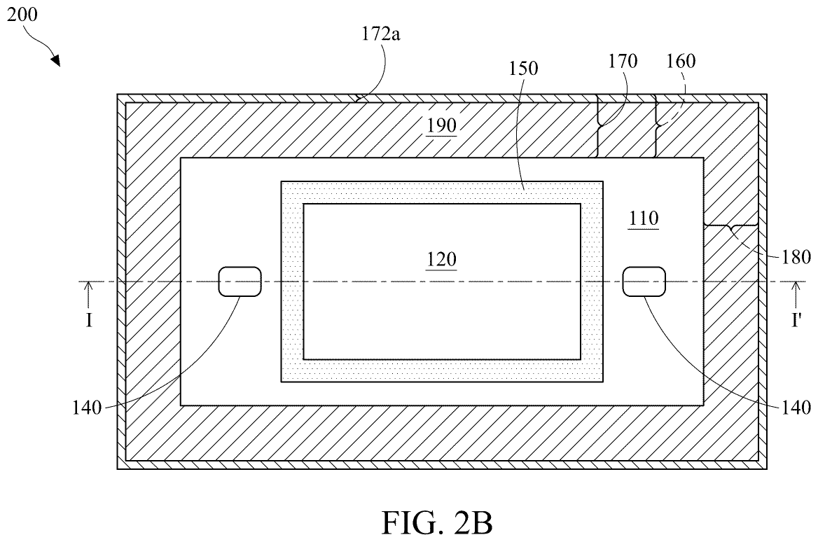

FIG. 2A is a cross-sectional view of a chip package structure 200, in accordance with some embodiments. FIG. 2B is a top view of the chip package structure 200 of FIG. 2A, in accordance with some embodiments. FIG. 2A is a cross-sectional view illustrating the chip package structure 200 along a sectional line I-I′ in FIG. 2B, in accordance with some embodiments.

As shown in FIGS. 2A and 2B, the chip package structure 200 is similar to the chip package structure 100 of FIG. 1E, and in this embodiment the anti-warpage structure 190 exposes a portion 172a of a top surface 172 of the ring structure 170, in accordance with some embodiments. As shown in FIG. 2B, the portion 172a surrounds the anti-warpage structure 190 and the chip structure 120, in accordance with some embodiments. The inner sidewalls of the anti-warpage structure 190 and the ring structure 170 are coterminous, in accordance with some embodiments. The outer sidewalls of the anti-warpage structure 190 and the ring structure 170 are spaced apart by the exposed top surface 172, in accordance with some embodiments.

The ring structure 170 has a width W1 and the anti-warpage structure 190 has a width W2, in accordance with some embodiments. The widths W1 and W2 being measured between sidewalls of a same sections of the structures 170 and 190. The width W2 is smaller than the width W1 in accordance with some embodiments. Outer sidewalls of opposing sections of the ring structure 170 are separated by a width W3, in accordance with some embodiments. Outer sidewalls of opposing sections of the anti-warpage structure 190 are separated by a width W4, in accordance with some embodiments. The width W4 is smaller than the width W3 in accordance with some embodiments.

Since the coefficient of thermal expansion of the anti-warpage structure 190 is greater than the coefficient of thermal expansion of the ring structure 170, the shrinkage of the anti-warpage structure 190 is greater than the shrinkage of the ring structure 170 after annealing processes, in accordance with some embodiments. Therefore, the anti-warpage structure 190 may be narrower than the ring structure 170.

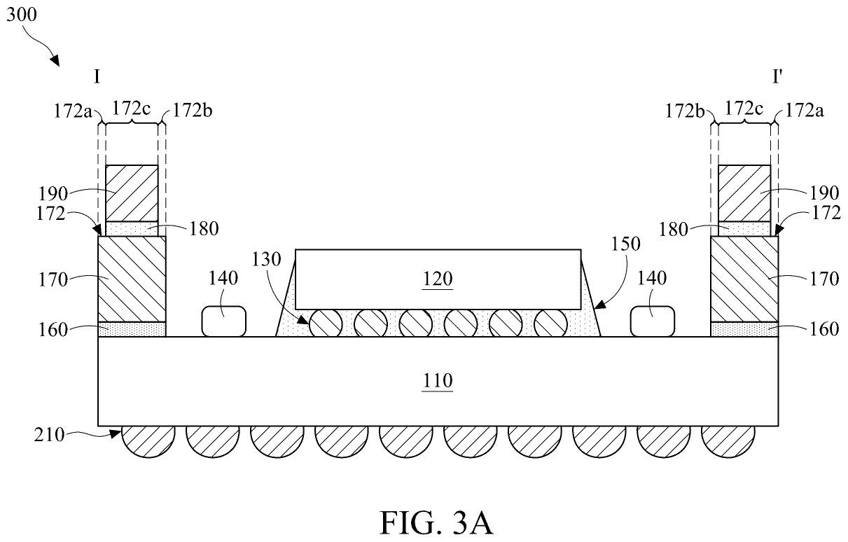

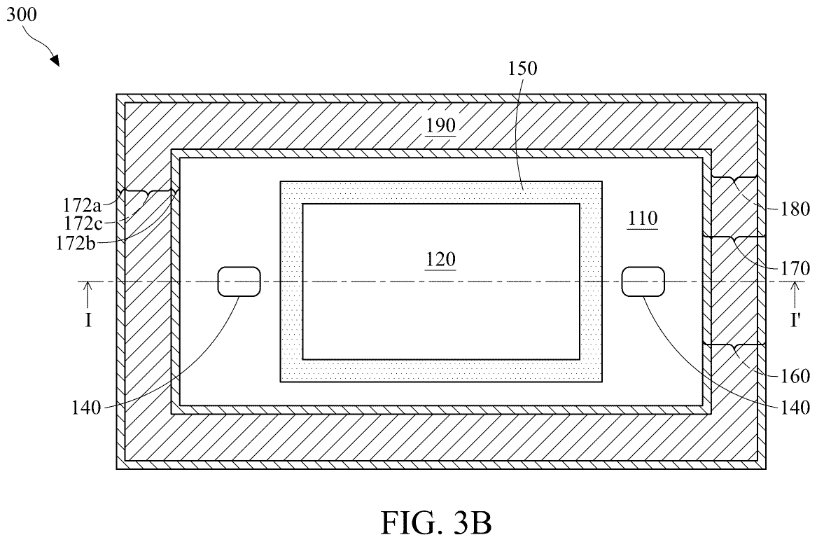

FIG. 3A is a cross-sectional view of a chip package structure 300, in accordance with some embodiments. FIG. 3B is a top view of the chip package structure 300 of FIG. 3A, in accordance with some embodiments. FIG. 3A is a cross-sectional view illustrating the chip package structure 300 along a sectional line I-I′ in FIG. 3B, in accordance with some embodiments.

As shown in FIGS. 3A and 3B, the chip package structure 300 is similar to the chip package structure 200 of FIG. 2A and 2B, and in this embodiment the anti-warpage structure 190 exposes portions 172a and 172b of the top surface 172 of the ring structure 170, in accordance with some embodiments. The anti-warpage structure 190 is over a portion 172c of the top surface 172 of the ring structure 170, in accordance with some embodiments. The portion 172c is between the portions 172a and 172b, in accordance with some embodiments.

As shown in FIG. 3B, the portion 172a surrounds the portions 172b and 172c, the anti-warpage structure 190 and the chip structure 120, in accordance with some embodiments. As shown in FIG. 3B, the portion 172b surrounds the chip structure 120, in accordance with some embodiments.

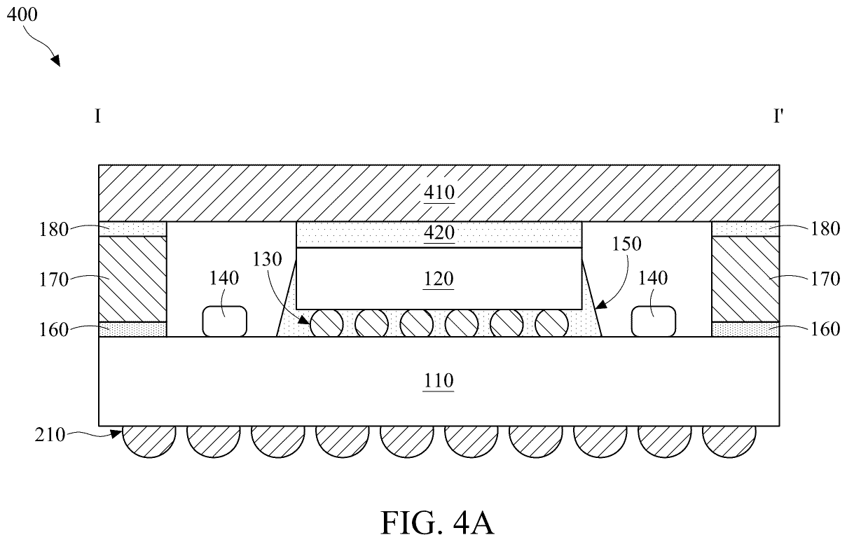

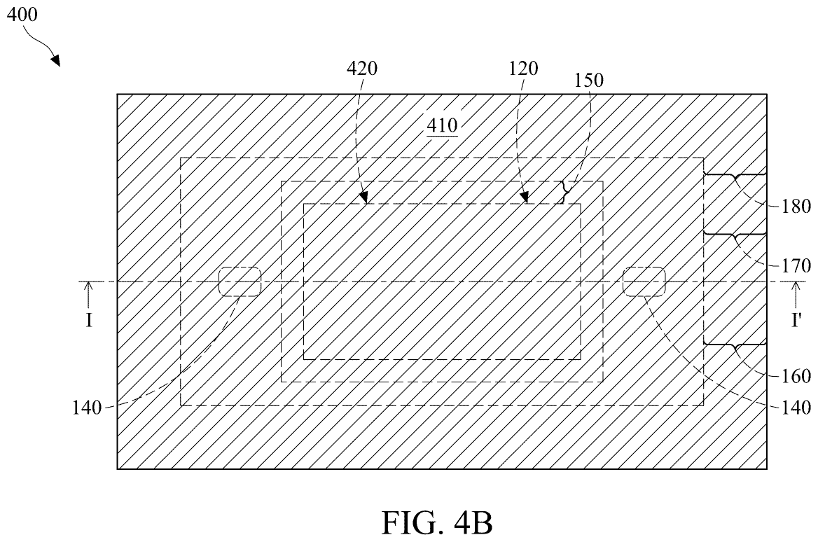

FIG. 4A is a cross-sectional view of a chip package structure 400, in accordance with some embodiments. FIG. 4B is a top view of the chip package structure 400 of FIG. 4A, in accordance with some embodiments. FIG. 4A is a cross-sectional view illustrating the chip package structure 400 along a sectional line I-I′ in FIG. 4B, in accordance with some embodiments.

As shown in FIGS. 4A and 4B, the chip package structure 400 is similar to the chip package structure 100 of FIG. 1E, and in this embodiment the anti-warpage structure 410 of the chip package structure 400 includes a lid structure, in accordance with some embodiments. The anti-warpage structure 410 covers the chip structure 120, the conductive bumps 130, the devices 140, the underfill layer 150, and the ring structure 170, in accordance with some embodiments.

The anti-warpage structure 410 is made of a high CTE and high thermal conductivity material, such as a metal material (aluminum or copper), an alloy material (e.g., stainless steel), aluminum-silicon carbide (AlSiC), or another suitable material with a higher CTE than the ring structure 170 and the wiring substrate 110, in accordance with some embodiments.

The chip package structure 400 further includes a heat conductive layer 420, in accordance with some embodiments. The heat conductive layer 420 is formed over the chip structure 120, in accordance with some embodiments. The thermal conductivity of the heat conductive layer 420 is greater than the thermal conductivity of the chip structure 120, in accordance with some embodiments. The heat conductive layer 420 is in direct contact with the chip structure 120 and the anti-warpage structure 410, and heat is transferred from the chip structure 120 to the anti-warpage structure 410 through the heat conductive layer 420, in accordance with some embodiments.

The heat conductive layer 420 is made of a polymer material including silicone or epoxy, in accordance with some embodiments. The polymer material is doped with particles, which are made of aluminum oxide or zinc oxide, in accordance with some embodiments. The heat conductive layer 420 is formed using a dispensing process, in accordance with some embodiments.

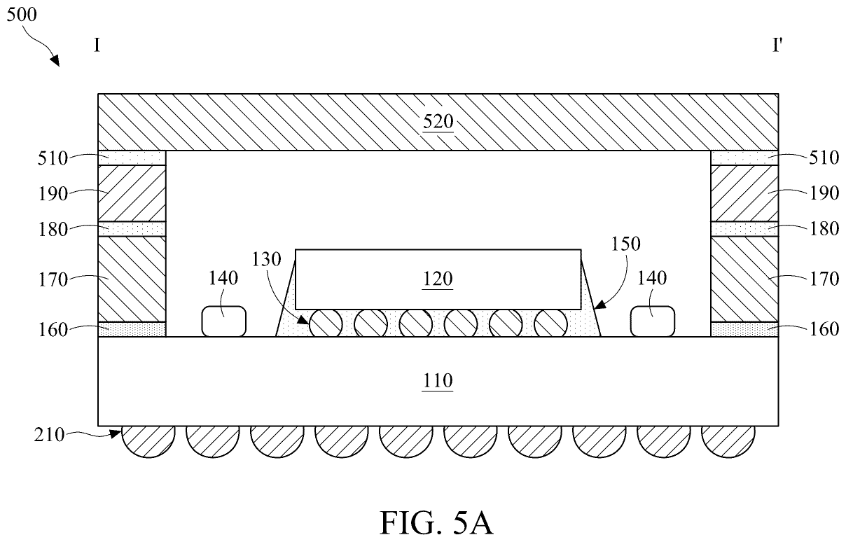

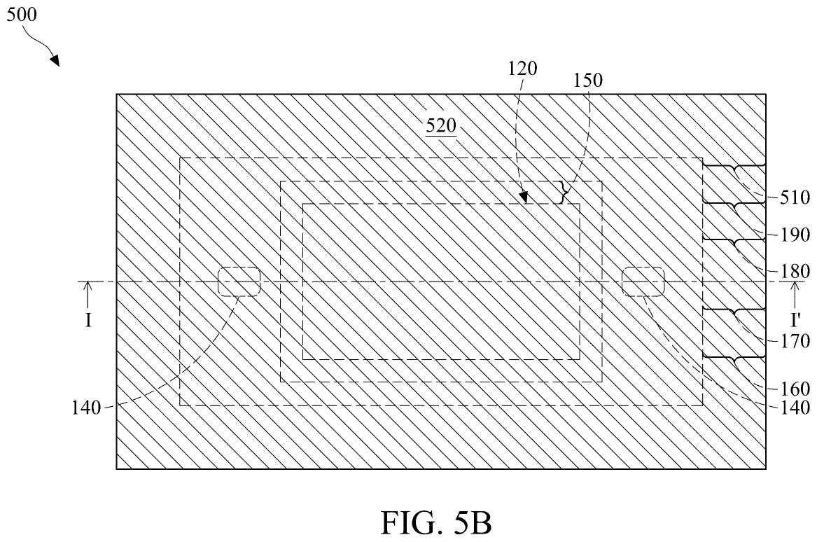

FIG. 5A is a cross-sectional view of a chip package structure 500, in accordance with some embodiments. FIG. 5B is a top view of the chip package structure 500 of FIG. 5A, in accordance with some embodiments. FIG. 5A is a cross-sectional view illustrating the chip package structure 500 along a sectional line I-I′ in FIG. 5B, in accordance with some embodiments.

As shown in FIGS. 5A and 5B, the chip package structure 500 is similar to the chip package structure 100 of FIG. 1E, and in this embodiment the chip package structure 500 further includes an adhesive layer 510 and an anti-warpage structure 520, in accordance with some embodiments.

The adhesive layer 510 is formed over the anti-warpage structure 190, in accordance with some embodiments. The adhesive layer 510 is made of a polymer material such as epoxy or silicone, in accordance with some embodiments. The adhesive layer 510 is formed using a dispensing process, in accordance with some embodiments.

The anti-warpage structure 520 includes a lid structure, in accordance with some embodiments. The anti-warpage structure 520 is bonded to the adhesive layer 510, in accordance with some embodiments. The adhesive layer 510 is between the anti-warpage structure 520 and the anti-warpage structure 190, in accordance with some embodiments.

The anti-warpage structure 520 covers the chip structure 120, the conductive bumps 130, the devices 140, the underfill layer 150, the ring structure 170, the anti-warpage structure 190, and the adhesive layers 160, 180 and 510, in accordance with some embodiments.

The anti-warpage structure 190 is between the ring structure 170 and the anti-warpage structure 520, in accordance with some embodiments. The coefficient of thermal expansion of the anti-warpage structure 190 is greater than the coefficient of thermal expansion of the ring structure 170, in accordance with some embodiments. The coefficient of thermal expansion of the anti-warpage structure 520 is greater than the coefficient of thermal expansion of the ring structure 170, in accordance with some embodiments.

The anti-warpage structure 520 is made of a high CTE and high thermal conductivity material, such as a metal material (aluminum or copper), an alloy material (e.g., stainless steel), aluminum-silicon carbide (AlSiC), or another suitable material with a higher CTE than the ring structure 170 and the wiring substrate 110, in accordance with some embodiments.

In some embodiments, the anti-warpage structure 520 and the anti-warpage structure 190 are made of the same material. In some embodiments, the anti-warpage structure 520 and the anti-warpage structure 190 are made of the different materials. The CTE of the anti-warpage structure 520 is greater than the CTE of the anti-warpage structure 190, in accordance with some embodiments.

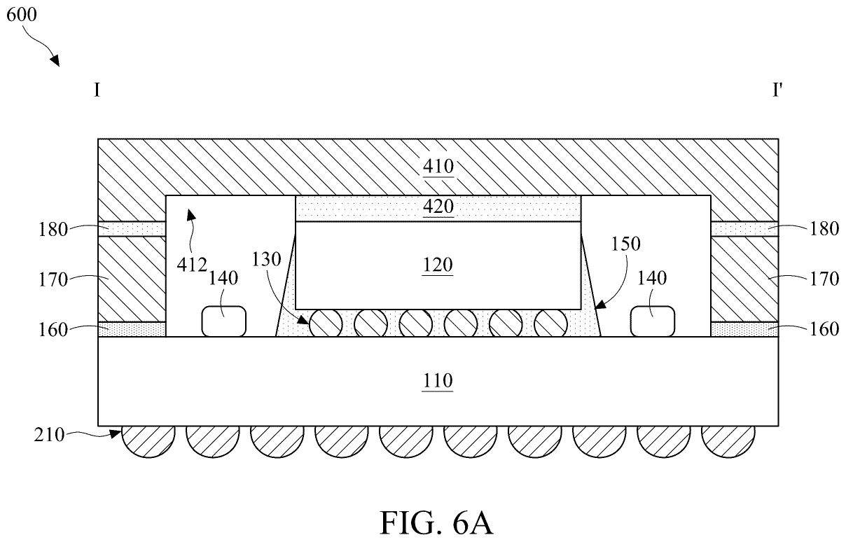

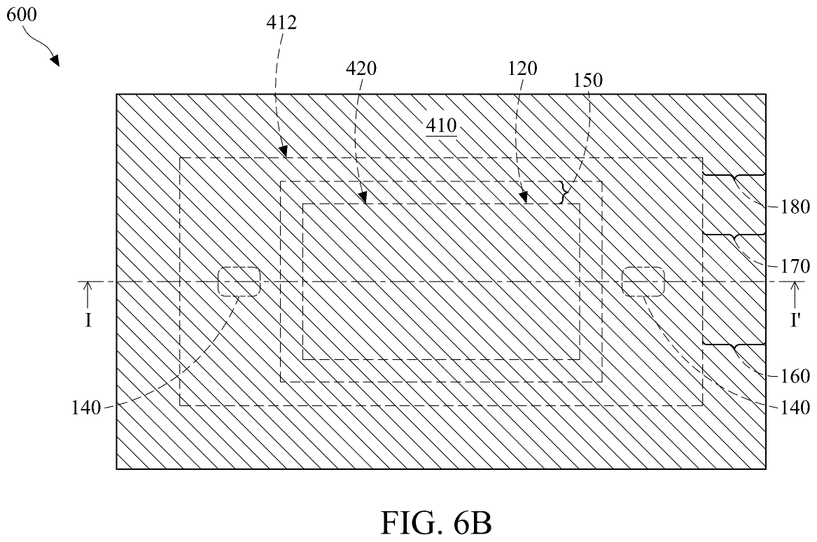

FIG. 6A is a cross-sectional view of a chip package structure, in accordance with some embodiments. FIG. 6B is a top view of the chip package structure of FIG. 6A, in accordance with some embodiments. FIG. 6A is a cross-sectional view illustrating the chip package structure along a sectional line I-I′ in FIG. 6B, in accordance with some embodiments.

As shown in FIGS. 6A and 6B, the chip package structure 600 is similar to the chip package structure 400 of FIG. 4A, and in this embodiment the anti-warpage structure 410 of the chip package structure 600 further has a recess 412, in accordance with some embodiments.

The heat conductive layer 420 is in the recess 412 of the anti-warpage structure 410, in accordance with some embodiments. The chip structure 120 is partially in or under the recess 412, in accordance with some embodiments.

Processes and materials for forming the chip package structures 200, 300, 400, 500 and 600 may be similar to, or the same as, those for forming the chip package structure 100 described above. Elements designated by the same or similar reference numbers as those in FIGS. 1A to 6B have the same or similar structures and the materials. Therefore, the detailed descriptions thereof will not be repeated herein.

In accordance with some embodiments, chip package structures and methods for forming the same are provided. The methods (for forming the chip package structure) form a low CTE and high rigidity ring structure over a wiring substrate to form a low CTE and high rigidity equivalent body. The methods form a high CTE anti-warpage structure over the equivalent body. Since the equivalent body with a low CTE, the CTE mismatch between the anti-warpage structure and the equivalent body is increased, which reduces the warpage of the chip package structures.

In accordance with some embodiments, a chip package structure is provided. The chip package structure includes a wiring substrate. The chip package structure includes a chip structure over the wiring substrate. The chip package structure includes a first ring structure over the wiring substrate and surrounding the chip structure. A first coefficient of thermal expansion of the first ring structure is less than a second coefficient of thermal expansion of the wiring substrate. The chip package structure includes an anti-warpage structure over the first ring structure. A third coefficient of thermal expansion of the anti-warpage structure is greater than the first coefficient of thermal expansion of the first ring structure.

In accordance with some embodiments, a chip package structure is provided. The chip package structure includes a wiring substrate. The chip package structure includes a chip structure over the wiring substrate. The chip package structure includes a ring structure over the wiring substrate and surrounding the chip structure. A first coefficient of thermal expansion of the ring structure is less than a second coefficient of thermal expansion of the wiring substrate. The chip package structure includes an anti-warpage structure over the ring structure. A third coefficient of thermal expansion of the anti-warpage structure is greater than the second coefficient of thermal expansion of the wiring substrate.

In accordance with some embodiments, a method for forming a chip package structure is provided. The method includes bonding a chip structure to a wiring substrate. The method includes bonding a ring structure to the wiring substrate. The ring structure surrounds the chip structure, and a first coefficient of thermal expansion of the ring structure is less than a second coefficient of thermal expansion of the wiring substrate. The method includes bonding an anti-warpage structure to the ring structure. A third coefficient of thermal expansion of the anti-warpage structure is greater than the first coefficient of thermal expansion of the ring structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a chip structure to a wiring substrate;
bonding a first ring structure to the wiring substrate, wherein the first ring structure surrounds the chip structure;
bonding a second ring structure to the first ring structure;
bonding an anti-warpage structure to the second ring structure;
wherein each of the second ring structure and the anti-warpage structure has a higher coefficient of thermal expansion and a smaller width than the structure immediately below it, and wherein the bonding of the second ring structure and the anti-warpage structure results in partial exposure of each underlying structure.

2. The method of claim 1, further comprising forming a first adhesive layer between the wiring substrate and the first ring structure.

3. The method of claim 2, further comprising forming a second adhesive layer between the first ring structure and the second ring structure.

4. The method of claim 3, further comprising forming a third adhesive layer between the second ring structure and the anti-warpage structure.

5. The method of claim 1, further comprising forming conductive bumps on a surface of the wiring substrate opposite to the chip structure.

6. The method of claim 1, further comprising forming an underfill layer between the chip structure and the wiring substrate.

7. The method of claim 1, wherein the first ring structure has a lower coefficient of thermal expansion than the wiring substrate.

8. The method of claim 1, further comprising bonding passive devices to the wiring substrate adjacent to the chip structure.

9. A semiconductor device, comprising:
a wiring substrate;
a chip structure bonded to the wiring substrate;
a first ring structure surrounding the chip structure;
an anti-warpage structure over the first ring structure;
wherein the first ring structure has a lower coefficient of thermal expansion than the wiring substrate, the anti-warpage structure has a higher coefficient of thermal expansion than the first ring structure, and the anti-warpage structure exposes a portion of a top surface of the first ring structure;
a first adhesive layer between the wiring substrate and the first ring structure; and
a second adhesive layer between the first ring structure and the anti-warpage structure.

10. The semiconductor device of claim 9, further comprising conductive bumps on a surface of the wiring substrate opposite to the chip structure.

11. The semiconductor device of claim 9, further comprising an underfill layer between the chip structure and the wiring substrate.

12. The semiconductor device of claim 9, further comprising passive devices bonded to the wiring substrate adjacent to the chip structure.

13. The semiconductor device of claim 9, wherein the anti-warpage structure comprises a ring structure.

14. The semiconductor device of claim 9, wherein the anti-warpage structure comprises a lid structure covering the chip structure and the first ring structure.

15. A method, comprising:
bonding a chip structure to a wiring substrate;
attaching a ring structure to the wiring substrate, wherein the ring structure has a coefficient of thermal expansion lower than the wiring substrate;
bonding a first anti-warpage structure to the ring structure, wherein the first anti-warpage structure is in the form of a ring;
applying an adhesive layer over the first anti-warpage structure;
attaching a second anti-warpage structure over the adhesive layer, wherein the second anti-warpage structure is in the form of a lid covering the entire assembly; and
wherein each of the first and second anti-warpage structures has a higher coefficient of thermal expansion than the structure immediately below it.

16. The method of claim 15, further comprising forming a heat conductive layer between the chip structure and the second anti-warpage structure.

17. The method of claim 16, wherein the heat conductive layer comprises a polymer material doped with thermally conductive particles.

18. The method of claim 15, further comprising forming a recess in the second anti-warpage structure above the chip structure.

19. The method of claim 15, further comprising:
forming a first adhesive layer between the wiring substrate and the ring structure;
forming a second adhesive layer between the ring structure and the first anti-warpage structure; and
wherein the first adhesive layer comprises a polymer material, and the second adhesive layer comprises a combination of polymer and metal or a polymer.

20. The method of claim 15, further comprising:
forming conductive bumps on a surface of the wiring substrate opposite to the chip structure;
forming an underfill layer between the chip structure and the wiring substrate;
bonding passive devices to the wiring substrate adjacent to the chip structure; and
wherein the ring structure comprises a ceramic material or a nickel-iron alloy.
